(19) United States
(12) Patent Application Publication
(10) Pub. No.: US 2012/0148871 A1
(43) Pub. Date: Jun. 14, 2012

(54) Magnesium Components with Improved Corrosion Protection

(75) Inventors: Michael Störmer, Hamburg (DE); Carsten Blawert, Lauenburg (DE); Yuanding Huang, Geesthacht (DE); Daniel Höche, Hamburg (DE); Wolfgang Dietzel, Geesthacht (DE); Karl U. Kainer, Hohnstorf (DE)

(73) Assignee: Helmholtz-Zentrum Geesthacht Zentrum fur Material-und Kustenforschung GmbH, Geesthacht (DE)

(21) Appl. No.: 13/302,418

(22) Filed: Nov. 22, 2011

(30) Foreign Application Priority Data
Dec. 8, 2010 (EP) EP10194110.2

(51) Int. Cl. B32B 15/01; C23C 14/35; C23C 16/06

(52) U.S. Cl. 428/649; 427/250; 427/598

(57) ABSTRACT

The present invention relates to magnesium components with improved corrosion protection. The components are coated with a vitreous binary Mg—X alloy or a vitreous ternary Mg—X—Y alloy, where X is an element selected from the group consisting of the elements of main group III, of transition group III or rare earth elements of the Periodic Table of the Elements, and Y is an element selected from the group consisting of the elements of main group III or IV, of transition group III or IV or rare earth elements of the Periodic Table of the Elements. The coating is produced by means of physical vapor deposition processes, such as cathode ray atomization.

The present invention relates to magnesium components with improved corrosion protection.

### BACKGROUND OF THE INVENTION

With the ever growing demands made on the energy efficiency of various products, lightweight material construction is playing an ever greater role in the development of new products. In this respect, magnesium alloys have already been used for a relatively long time on account of their favorable strength-to-density ratio. However, the greatest barrier for the use of magnesium alloys continues to be the lack of corrosion resistance of unprotected surfaces. For this reason, this group of materials is still excluded from special fields of use in the automotive industry and in air travel.

In the absence of moisture, magnesium reacts with atmospheric oxygen to form magnesium oxide (MgO), which forms a very thin gray layer on the material surface. Magnesium oxide has a smaller molar volume than the underlying magnesium matrix and therefore forms a porous layer. The so-called Pilling-Bedworth ratio describes the quotient of molar volume of the layer-forming oxide and the molar volume of the base material and is 0.84 in the case of magnesium. Therefore, magnesium oxide cannot protect the material as well as aluminum oxide which forms on aluminum materials, for example, which has a Pilling-Bedworth ratio of 1.38.

The corrosion behavior of magnesium components is dependent not only on the atmospheric humidity, but also on the chemical composition of the atmosphere. The various magnesium materials display areal and hole-like attack as forms of corrosion. The typical corrosion rate for magnesium materials is 0.5 to 50 mm/year.

Magnesium components are usually protected against corrosion by applying protective layers to the component. Protective layers are commonly divided into the following categories: (a) chemical conversion layers, (b) electrochemical protective layers, (c) non-metallic protective layers and (d) physically changed surfaces.

Chemical conversion layers form upon treatment in aqueous solutions containing chromic acid. Recently, RoHS-compliant conversion layers have also been provided for the electrical, electronics and automotive industries. Instead of containing Cr⁶⁺, these only contain Cr³⁺ or are even chromium-free. The chromating layers are very thin and bring about no or only minimal changes in mass. Depending on the application, transparent or yellow chromating layers are used. On account of the low abrasion resistances, the chemical conversion layer does not provide any protection against mechanical wear.

A further possible way to produce corrosion protection for magnesium components is to form electrochemical layers, for example by anodizing or plasma electrolytic oxidation. A plurality of processes are available for anodizing magnesium, for example a) HAE, b) Magoxide-Coat and more recently c) Anomag processes. The HAE process is considered to be fluoride anodizing or galvanic anodizing using alternating current. HAE layers are made up of spinels of the elements magnesium, aluminum and manganese, i.e. of mixed oxides of divalent and trivalent metal ions, and are classed among the anodic conversion layers. The brittle layers are established approximately half into the material and half to the outside. HAE layers are applied as wear protection and as corrosion protection and also serve as an undercoat for paints.

The galvanizing of magnesium is significantly more difficult than, for example, the deposition of metallic coats on steel or brass. The baths which are customarily used for these materials are unsuitable for magnesium alloys. The chemical activity of magnesium in such baths leads to spontaneous electroless plating of loose, poorly adhering layers.

The mode of operation of the coatings based on organic paints consists primarily of preventing water and oxygen, which are corrosion-promoting compounds, from accessing the metal surface. This prevention of passage is determined by the diffusion resistance of the layer of paint and by the adhesion thereof to the substrate under the action of moisture, which is known as the wet-film adhesion. Epoxy resins are said to provide the best corrosion protection for magnesium components, followed by epoxy-polyester hybrid resins and polyester resins.

Organically coated magnesium components are sensitive to filiform corrosion and are more susceptible thereto than aluminum components.

If a defect is present, metallic and other conductive coatings can cause contact corrosion.

### SUMMARY OF THE INVENTION

It is therefore an object of the present invention to provide magnesium components with improved corrosion protection, in the case of which contact corrosion does not occur if a defect is present. It is a further object of the present invention to provide a magnesium component having a corrosion rate of less than 0.01 mm/year.

The object is achieved by a magnesium component, which is coated with a vitreous binary Mg—X alloy or a vitreous ternary Mg—X—Y alloy, where X is an element selected from the group consisting of the elements of main group III, of transition group III or rare earth elements of the Periodic Table of the Elements, and Y is an element selected from the group consisting of the elements of main group III or IV, of transition group III or IV or rare earth elements of the Periodic Table of the Elements.

The alloys Mg—X and Mg—X—Y can also contain further elements Z, etc. However, these further elements should preferably only be present in small quantities of <5 at. %, more preferably <1 at. %, particularly preferably <0.5 at. % and most preferably <0.1 at. % in the magnesium alloy of the coating.

### DEFINITIONS

According to the invention, the term “magnesium component” denotes any component which is produced from magnesium metal or a magnesium alloy. These may be components for motor vehicles, aircraft, ships, machines or the like, but also medical implants such as bone implants or the like. The magnesium alloy of the magnesium component can contain any quantity of magnesium, e.g. from 1 to 100 atom % (at. %). It is preferable for the magnesium alloy of the magnesium component to contain at least 50 at. %, particularly preferably at least at. %, of magnesium. It is preferable, but not necessary, for the magnesium alloy to also contain at least one element selected from the group consisting of the elements of main group III, of transition group III or rare earth elements of the Periodic Table of the Elements. By way of example, the magnesium component can be produced from an AZ31, AZ91, AE42, ZM21, ZK31 or ZE41 alloy or any other customary magnesium alloy.

The term “vitreous”, “vitreous alloy” or “metallic glass” is common in industry and denotes an amorphous alloy which is distinguished by the fact that it does not form a crystal structure and the material remains in a type of arrangement without periodicity, i.e. without a long-range order, similar to the atoms in a melt. Even though the alloys are denoted as amorphous, they nevertheless always have a pronounced short-range order, both topologically and chemically.

The term “main group III of the Periodic Table of the Elements” comprises the elements boron (B), aluminum (Al), gallium (Ga), indium (In) and thallium (Tl). The term “main group IV of the Periodic Table of the Elements” comprises the elements carbon (C), silicon (Si), germanium (Ge), tin (Sn) and lead (Pb). The term “transition group III of the Periodic Table of the Elements” comprises the elements scandium (Sc), yttrium (Y), lanthanum (La) and actinium (Ac). The term “transition group IV of the Periodic Table of the Elements” comprises the elements titanium (Ti), zirconium (Zr) and hafnium (Hf). The term “rare earth elements” comprises the elements of the lanthanoids and the elements of the actinides. In the present case, the collective term “lanthanoids” is understood to mean the 14 elements which follow lanthanum, i.e. cerium (Ce), praseodymium (Pr), neodymium (Nd), promethium (Pm), samarium (Sm), europium (Eu), gadolinium (Gd), terbium (Tb), dysprosium (Dy), holmium (Ho), erbium (Er), thulium (Tm), ytterbium (Yt) and lutetium (Lu). These are often present in the form of mixed metals. In the context of the present invention, the term “rare earth element” also comprises mixed metals of the rare earth elements or lanthanoids. This means that such a mixed metal can be construed as “an element” X or Y.

### BRIEF DESCRIPTION OF THE DRAWINGS

FIG. 1 is a graph showing the corrosion rate (solid line) in mm/year and the free corrosion potential (dashed line) in mV depending on the aluminum concentration (in % by weight) of the coating;

FIG. 2 is a graph showing the corrosion rate in mm/year depending on the gadolinium concentration (in at. %) of the coating; and

FIG. 3 shows the corrosion rate in mm/year depending on the lanthanum concentration (in at. %) of the coating.

### DETAILED DESCRIPTION OF THE INVENTION

The present invention relates to magnesium components, which are coated with a vitreous binary Mg—X alloy or a vitreous ternary Mg—X—Y alloy, where X is an element selected from the group consisting of the elements of main group III, of transition group III or rare earth elements of the Periodic Table of the Elements, and Y is an element selected from the group consisting of the elements of main group III or IV, of transition group III or IV or rare earth elements of the Periodic Table of the Elements. It is preferable for the components to be coated with a binary Mg—X alloy, where X is selected with particular preference from the group consisting of Al, Gd, La and a mixed metal of the group of the lanthanoids. The components can alternatively be coated with a ternary Mg—X—Y alloy, where X is selected with particular preference from the group consisting of Al, Gd, La and a mixed metal of the group of the lanthanoids and Y is selected with particular preference from the group consisting of B, Si and Zr or is a further element from the group consisting of Al, Gd or La.

Preferred atomic ratios in the binary alloy Mg—X are 90-50 Mg:50-10 X, preferably 80-50 Mg:50-20 X, particularly preferably 75-60 Mg:25-40 X, and in the ternary alloy Mg—X—Y are 90-50 Mg:50-10 X:25-0 Y, preferably 80-50 Mg:50-20 X:25-0 Y, particularly preferably 75-60 Mg:25-40 X:10-5 Y. The corrosion properties of the layers produced have particularly low corrosion rates, if the contents of the components Mg—X or Mg—X—Y correspond approximately to the content of the intermetallic phases which would form according to the state diagram in thermodynamic equilibrium.

According to a first embodiment, the components are coated with a binary Mg—X alloy in which X is Al. Since it is possible for galvanic corrosion to occur, the potential of the coating should be lower than that of the substrate. This is the case if the aluminum content is in the range of 0 to 50 at. %. Good passivation is achieved in the range of about 35-50 at. % of Al, preferably about 36 to 45 at. % of Al, and in particular about 40-42 at. % of Al. In this range, the layers likewise have very low corrosion rates, with a minimum of about 5 μm/year.

Further optimization is achieved if a further element is added to the alloy to form an Mg—X—Y alloy, in which Y is an element selected from the group consisting of the elements of main group III or IV, of transition group III or IV or rare earth elements of the Periodic Table of the Elements. Y is preferably selected from the group consisting of Zr and La. The Y content is preferably 0 to 25 at. %, preferably 1 to 10 at. %.

According to a second embodiment, the components are coated with a binary Mg—X alloy in which X is Gd. The Gd content is preferably 10 to 50 at. %. Further optimization is achieved if a further element is added to the alloy to form an Mg—X—Y alloy, in which Y is an element selected from the group consisting of the elements of main group III or IV, of transition group III or IV or rare earth elements of the Periodic Table of the Elements. Y is preferably selected from the group consisting of B, Si, Zr and Al. The Y content is preferably 0 to 25 at. %, preferably 1 to 10 at. %.

According to a third embodiment, the components are coated with a binary Mg—X alloy in which X is La. The La content is preferably 10 to 50 at. %. Further optimization is achieved if a further element is added to the alloy to form an Mg—X—Y alloy, in which Y is an element selected from the group consisting of the elements of main group III or IV, of transition group III or IV or rare earth elements of the Periodic Table of the Elements. Y is preferably selected from the group consisting of B, Si, Zr and Al. The Y content is preferably 0 to 25 at. %, preferably 1 to 10 at. %.

The coatings according to the invention can be produced by means of physical vapor deposition processes, preferably by cathode ray atomization (sputtering). Cathode ray atomization processes (sputtering processes) for coating substrates, in which ions, preferably noble gas ions such as argon ions, are produced in a vacuum chamber by a plasma and are accelerated in the direction of a cathode where they strike against a material to be atomized, i.e. the coating material (target), are generally known. Such a process is described, for example, in EP 1 826 811 A1, to which reference is made here. A magnet is preferably fitted under the target (magnetron atomization, magnetron sputtering). This has the advantage that no segregation of alloys occurs.

It is preferable to use combinations of two coating materials for producing a binary Mg—X alloy on the surface of the component. In the present context, the term “combination” means a combination of at least two separate coating materials (targets) which are atomized by different cathode rays. Thus, by way of example, use is preferably made of a combination of magnesium as a first coating material and at least one second coating material, where the second coating material (X) is an element selected from the group consisting of the elements of main group III, of transition group III or IV or rare earth elements of the Periodic Table of the Elements, and Y is an element selected from the group consisting of the elements of main group III or IV, of transition group III or IV or rare earth elements of the Periodic Table of the Elements. The first and the second coating material are preferably atomized by cathode rays which are produced by different generators.

The same also applies to the production of a ternary Mg—X—Y alloy on the surface of the component. To this end, use is preferably made of a combination of magnesium as a first coating material, a second coating material (X) and a third coating material (Y), where X is defined as above and Y is an element selected from the group consisting of the elements of main group III or IV, of transition group III or IV or rare earth elements of the Periodic Table of the Elements. For production, use can also be made equivalently of alloy targets having a composition corresponding to the vitreous binary or ternary or more complex alloy layer or a plurality of alloy targets of differing composition, which only provide the desired layer composition on the substrate.

Before the cathode ray atomization, the samples are under a high vacuum in an installation, preferably at a base pressure of less than 10⁻⁷ mbar. The required sputtering gas is preferably argon and the preferred sputtering gas pressure is 0.0001 to 1 mbar. Material is thus removed from the target, the cathode ray atomization, with a kinetic energy of the Ar ions of preferably 5 to 50 eV, in particular 5 to 10 eV.

The process according to the invention makes it possible to achieve high quench rates in the region of higher than about 10⁶ K/s. When setting the quench rates of higher than about 10⁶ K/s, which are preferred according to the invention, the vitreous alloys according to the invention form with grain sizes in the region of preferably <10 nm (determined by means of transmission electron microscopy), which do not allow a long-range order to be identified. Such a microstructure cannot be produced by conventional coating processes.

The preferred layer thickness of the coating is about 5 nm to 500 μm, particularly preferably 1 to 10 μm.

The magnesium components according to the invention have a low corrosion rate of less than 0.01 mm/year. Furthermore, the magnesium components have cathodic corrosion protection.

The invention will now be explained on the basis of the following examples, which are not intended to restrict the invention.

### Example 1

Various magnesium-aluminum coatings having different Mg:Al ratios were produced on silicon and AZ31 alloys by sputtering two different targets, specifically an Mg target and an Al target, with cathode rays of differing energy. The coating thickness was about 3 μm, the vacuum beforehand was about 10⁻⁷ mbar, and the sputtering gas was argon, which was used at a gas pressure of 0.2 Pa.

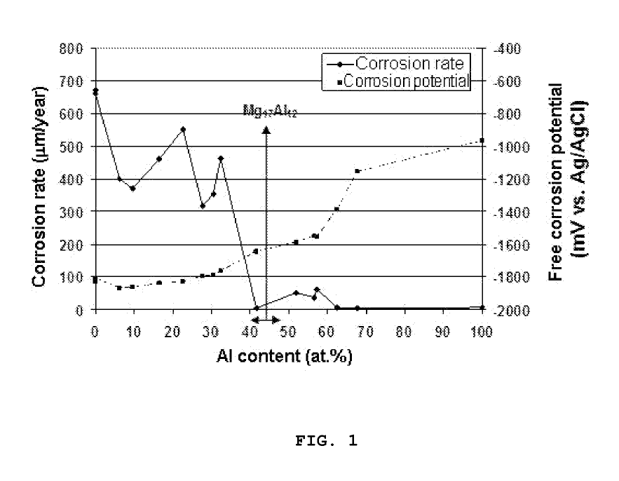

FIG. 1 shows the corrosion rate (solid line) in mm/year and the free corrosion potential (dashed line) in mV depending on the aluminum concentration (in % by weight) of the coating.

The corrosion potential of the coating is in the range of 0 to 50% by weight below the potential of the substrate (AZ31), which reduces the risk of galvanic corrosion. Good passivation is achieved in the range of 40-50 at. % of Al. In this range, the layers likewise have very low corrosion rates, with a minimum of about 5 μm/year.

Table 1 hereinbelow provides an overview of various properties of the alloys:

TABLE 1

| | | Mg | Al | | Layer | | | | | Free | | Passive | Break- |
|---|---|---|---|---|---|---|---|---|---|---|---|---|---|
| Mg: | Al: | Coating | Coating | Al | thick- | | | Grain | | corrosion | Corrosion | current | down |
| Power/ | Power/ | rate/ | rate/ | conc./ | ness/ | Roughness/ | dₕₖₗ/ | size/ | | potential/ | rate/ | density/ | potential/ |
| W | W | nm/s | nm/s | wt. % | μm | nm | nm | nm | Phases obtained | mV | μm/year | mA/cm² | mV |
| 160 | 0 | 0.815 | 0 | 0 | 2.5 | 33 | 2.608 | 29 | hcp-Mg | −1832 | 671 | Active | Active |
| | | | | | | | | | | | | dissolution | dissolution |
| 130 | 30 | 0.748 | 0.085 | 7 | 2.8 | 1.0 | 2.587 | 31 | Mg(Al) | −1870 | 399 | Active | Active |
| | | | | | | | | | | | | dissolution | dissolution |
| 160 | 60 | 0.887 | 0.095 | 11 | 2.8 | 1.3 | 2.578 | 27 | Mg(Al) | −1866 | 369 | Active | Active |
| | | | | | | | | | | | | dissolution | dissolution |
| 160 | 80 | 0.924 | 0.183 | 18 | 3.1 | 1.1 | 2.558 | 21 | Mg(Al) | −1841 | 460 | 0.0689 | −1433 |
| 160 | 140 | 0.920 | 0.269 | 25 | 3.3 | 2.0 | 2.550 | 28 | Mg(Al) + Al(Mg) | −1829 | 551 | 0.0469 | −1426 |
| 160 | 180 | 0.883 | 0.339 | 30 | 3.2 | 0.8 | 2.553 | 28 | Mg(Al) + Al(Mg) | −1799 | 316 | 0.0312 | −1366 |
| 140 | 180 | 0.750 | 0.330 | 33 | 3.0 | 0.6 | 2.554 | 27 | Mg(Al) + Al(Mg) | −1790 | 354 | 0.0323 | −1315 |
| 130 | 180 | 0.683 | 0.326 | 35 | 3.0 | 1.0 | 2.555 | 24 | Mg(Al) + Al(Mg) | −1764 | 462 | 0.0222 | −1262 |
| 90 | 180 | 0.441 | 0.314 | 44 | 3.2 | 1.0 | 2.545 | 13 | Mg(Al) + Al(Mg) | −1647 | 4 | 0.0027 | −1036 |
| 60 | 180 | 0.286 | 0.309 | 55 | 3.2 | 1.1 | 2.558 | 10 | Mg(Al) + Al(Mg) | −1590 | 52 | 0.0041 | −800 |
| 45 | 176 | 0.222 | 0.290 | 59 | 3.0 | 1.3 | | <10 | nanocrystalline | −1550 | 36 | 0.0038 | −796 |
| 50 | 180 | 0.225 | 0.302 | 60 | 2.8 | 1.0 | | <10 | nanocrystalline | −1557 | 62 | 0.0053 | −803 |
| 30 | 180 | 0.148 | 0.246 | 65 | 3.0 | 0.9 | | <10 | nanocrystalline | −1387 | 5 | 0.0130 | −790 |
| 20 | 180 | 0.131 | 0.275 | 70 | 2.9 | 2.1 | | <10 | nanocrystalline | −1157 | 4 | 0.0095 | −774 |
| 0 | 270 | 0.148 | 0.378 | 100 | 1.4 | 1.5 | 2.338 | 31 | fcc-Al | −969 | 6 | 0.0028 | −632 |

### Example 2

The corrosion properties can be further optimized if a further element is added to the alloy to form an Mg—Al—Y alloy. In the present case, the corrosion rate was investigated at different lanthanum contents:

| | | | Corrosion rate |
|---|---|---|---|
| At. % Mg | At. % Al | At. % La | (μm/year) |
| 91.3 | 7.6 | 1.1 | 154 |
| 52 | 36.9 | 11.1 | 16 |
| 45.3 | 53.3 | 1.4 | 122 |
| 43.1 | 53.8 | 3.1 | 123 |
| 41.8 | 36.3 | 21.9 | 21 |

### Example 3

As in Example 1, binary magnesium-gadolinium coatings having different Mg:Gd ratios were produced.

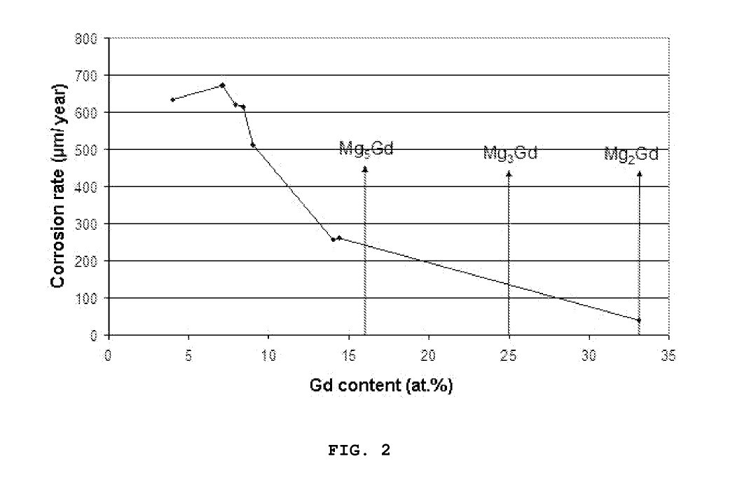

FIG. 2 shows the corrosion rate in mm/year depending on the gadolinium concentration (in at. %) of the coating.

As in the Mg—Al system, the corrosion rate in the Mg—Gd system also drops considerably as soon as the microstructure of the coating becomes nanocrystalline/amorphous.

### Example 4

In the Mg—Gd system, too, the addition of a third element can further reduce the corrosion, as shown in the following table:

| | | | Corrosion rate |
|---|---|---|---|
| At. % Mg | At. % Gd | At. % Y | (μm/year) |
| | | Y = B | |
| 56.2 | 42.3 | 1.5 | 7 |
| 51 | 42.6 | 6.4 | 31 |
| | | Y = Si | |
| 63.2 | 34.6 | 2.2 | 19 |
| 62 | 30.7 | 7.3 | 77 |
| 59.8 | 34.2 | 6.1 | 40 |
| | | Y = Zr | |
| 69.1 | 28.6 | 2.3 | 32 |
| 65 | 29 | 6.1 | 72 |
| 61.3 | 32.6 | 6.1 | 118 |
| | | X = Al | |
| 66.2 | 27.5 | 6.4 | 46 |
| 62.5 | 26.5 | 11 | 77 |

### Example 5

As in Examples 1 and 3, binary magnesium-lanthanum coatings having different Mg:La ratios were produced.

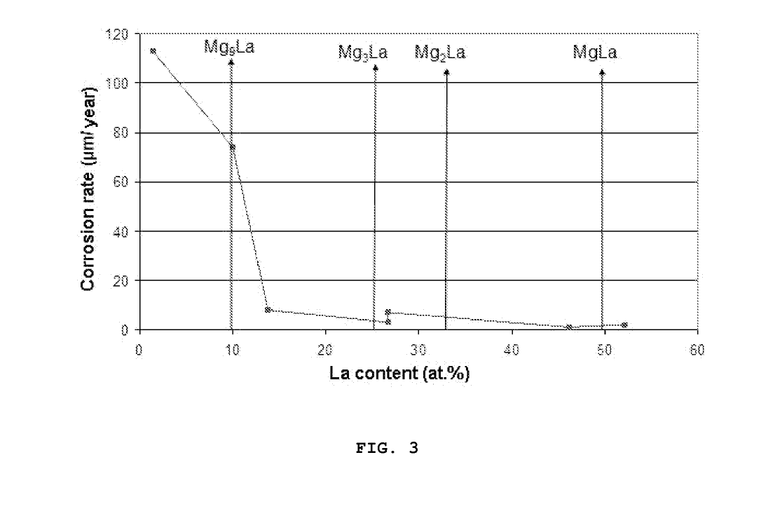

FIG. 3 shows the corrosion rate in mm/year depending on the lanthanum concentration (in at. %) of the coating.

Better results can be achieved with lanthanum than with gadolinium. Particularly low corrosion rates also occur here too in the vitreous state.

1. Component made of magnesium metal or a magnesium alloy, which is coated with a vitreous binary Mg—X alloy or a vitreous ternary Mg—X—Y alloy, where X is an element selected from the group consisting of the elements of main group III, of transition group III or rare earth elements of the Periodic Table of the Elements, and Y is an element selected from the group consisting of the elements of main group III or IV, of transition group III or IV or rare earth elements of the Periodic Table of the Elements, and wherein the atomic ratio Mg:X in the binary Mg—X alloy is 75:25 to 60:40 and the atomic ratio Mg:X:Y in the ternary Mg—X—Y alloy is 75:25:10 to 60:40:5.

2. Component according to claim 1, which is coated with a vitreous binary Mg—X alloy, where X is selected from the group consisting of Al, Gd, La and a mixed metal of the group of the lanthanoids.

3. Component according to claim 1, which is coated with a vitreous ternary Mg—X—Y alloy, where X is selected from the group consisting of Al, Gd, La and a mixed metal of the group of the lanthanoids and Y is selected from the group consisting of B, Si and Zr or is a further element from the group consisting of Al, Gd or La.

4. Component according to claim 1, wherein the layer thickness of the coating is 5 nm to 500 μm.

5. Component according to claim 1, which is produced from a magnesium alloy containing more than 70 at. % of magnesium.

6. Component according to claim 5, wherein the magnesium alloy is an AZ31 alloy.

7. Process for producing a coating comprising a vitreous binary Mg—X alloy or a vitreous ternary Mg—X—Y alloy on a component made of magnesium metal or a magnesium alloy by means of a physical vapor deposition process, where X and Y are defined as in claim 1.

8. Process according to claim 7, characterized in that a cathode ray atomization process (sputtering process) is used as the physical vapor deposition process.

9. Process according to claim 8, characterized in that the sputtering process is a magnetron sputtering process.

10. Process according to claim 8, characterized in that the coating comprising a vitreous binary Mg—X alloy or a vitreous ternary Mg—X—Y alloy is produced by a combinational process with element targets according to the number of components, wherein the power of the respective generators is controlled so as to achieve the desired favorable composition.

11. Process according to claim 8, characterized in that the coating comprising a vitreous binary Mg—X alloy or a vitreous ternary Mg—X—Y alloy is produced by using one or more alloy targets.

12. Process according to claim 9, characterized in that the coating comprising a vitreous binary Mg—X alloy or a vitreous ternary Mg—X—Y alloy is produced by a combinational process with element targets according to the number of components, wherein the power of the respective generators is controlled so as to achieve the desired favorable composition.

13. Process according to claim 9, characterized in that the coating comprising a vitreous binary Mg—X alloy or a vitreous ternary Mg—X—Y alloy is produced by using one or more alloy targets.

14. Component according to claim 2, wherein the layer thickness of the coating is 5 nm to 500 μm.

15. Component according to claim 3, wherein the layer thickness of the coating is 5 nm to 500 μm.

16. Component according to claim 2, which is produced from a magnesium alloy containing more than 70 at. % of magnesium.

17. Component according to claim 3, which is produced from a magnesium alloy containing more than 70 at. % of magnesium.

18. Process according to claim 7, wherein the magnesium alloy is an AZ31 alloy.

19. Process according to claim 8, wherein the magnesium alloy is an AZ31 alloy.

20. Process according to claim 9, wherein the magnesium alloy is an AZ31 alloy.
